(19) United States
(12) Patent Application Publication
(10) Pub. No.: US 2001/0023990 A1
(43) Pub. Date: Sep. 27, 2001

(54) Semiconductor device and method for fabricating same

(76) Inventors: Takashi Yokoyama, Tokyo (JP); Atsushi Nishizawa, Tokyo (JP)

Correspondence Address: Paul J. Esatto,Jr., Scully, Scott, Murphy & Presser, 400 Garden City Plaza, Garden City, NY, 11530, US

(21) Appl. No.: 09/741,326

(22) Filed: Dec. 20, 2000

(30) Foreign Application Priority Data
Dec. 20, 1999 (JP) 11-360975

(51) Int. Cl. H01L 21/44; H01L 23/48; H01L 23/52; H01L 29/40

(52) U.S. Cl. 257/773; 438/672

(57) ABSTRACT

A Cu wiring is formed on a higher layer than a Si substrate, and a via plug formed in a via hole communicates with the higher layer and the Si substrate. Etch rates of a HSQ layer surrounding a damascene and the first SiO₂ layer formed on the Si substrate change in different modes depending on the ratio of the flow rate of the first reactive gas to that of the second reactive gas. According to the aforementioned structure, a dual damascene structure of the semiconductor device in which there is no necessity for forming a stopper layer formed of silicon nitride between the insulating layers, and a capacitance between wirings can be reduced.

### FIELD OF THE INVENTION

This invention relates to a semiconductor device and a method for fabricating the same, and especially to a semiconductor device and or a method for fabricating the same in accordance with a dual damascene structure.

### BACKGROUND OF THE INVENTION

Recently, elevation of a speed of the data process by means of the LSI is desired earnestly year by year. The speed of the data process by means of the LSI is determined depending on an operational speed of a transistor in itself and a delay time of a signal propagation in a wiring.

The operational speed of the transistor which has affected the speed of the data process of the LSI up to now has been improved by miniatuarization of the transistor. However, in the LSI in which a LSI design rule is less than 0.12 μm, the delay time of the signal propagation in the wiring affects the speed of the data process of the LSI in a large way.

Accordingly, the metallic wiring formed of Cu, a specific conductivity of which is higher than that of Al, is actively developed in recent years. Since Cu is hard to be processed by dry etching in ordinary temperature, an effective method for forming a Cu wiring is that a SiO₂ layer is processed to form a damascene having the same shape as that of the Cu wiring and the damascene is filled with Cu.

As a method for forming the Cu wiring on an insulator, a technology called the damascene method in which the damascene formed on the insulator is filled with Cu is proposed. According to the damascene method, Cu filling the damascene is flattened by chemical mechanical polishing (CMP, hereinafter ).

A method in which only a single layer of the wiring is formed is called a single damascene method. In case that the damascene method is adopted, a dual damascene method in which a higher wiring and a via hole communicating with the higher and lower wirings are formed in a lump is promising. According to the dual damascene method, after the damascene for accommodating the higher wiring and the via hole communicating with a higher layer on which the higher wiring is situated and the Si substrate, Cu fills the damascene and the via hole, excessive Cu forced out from the damascene is polished by the CMP method, and the wiring and a via plug formed in the via hole can be formed in a lump. Since the wiring and the via plug can be formed in a lump according to the dual damascene method, fabricating cost can be reduced sharply.

An example of the conventional method for fabricating the semiconductor device having the dual damascene structure will be explained referring to FIGS. 1A to 1D, which show the steps of a fabrication process of the semiconductor device.

In general, there are plural methods for fabricating the semiconductor device having the dual damascene structure. Thereafter, an example of the via first process in which the via hole is etched in the first place and the damascene is etched subsequently will be explained.

First, the first SiO layer 403 which is 300 to 1000 nm thick is deposited on a Si substrate 401, which has beem provided with circuit elements, such as transistors etc., and the first wiring 402 (the lower wiring ). A SiN or SiON layer 404, which is 30 to 200 nm thick and serves as a stopper layer in case that the damascene for accommodating a Cu wiring 410 (the higher wiring ) is etched, is deposited on the first SiO₂ layer 403. The second SiO₂ layer 405 which is 100 to 500 nm thick is deposited on the SiO or SiON layer 404 (FIG. 1A ).

Subsequently, a via hole 407 is formed by using a patterned photo-resist 406 as a mask (FIG. 1B).

Next, after removing the photo-resist 406, a new photo-resist 408 is again patterned, and the damascene 411 is formed by etching. In case that the damascene 411 is formed by etching, etching is stopped surely just above the SiN or SiON layer 404 so that the layers blow the SiN or SiON layer 404 are not etched (FIG. 1C).

Finally, barrier metal 409, such as TaN etc., is deposited on inner surfaces of the damascene 411 and the via hole 407 by spattering. Next, the Cu layer 410 is formed by electroplating so that the damascene 411 is filled with Cu. Excessive Cu forced out from the damascene 411 is shaved and flattened by CMP to form the Cu dual damascene structure (FIG. 1, 4D).

Moreover, in case that the SiN (ε=7 to 8) or SiON (ε=5 to 6) layer with a high specific dielectric constant is used as the stopper layer as shown in FIG. 2, a capacitance between adjacent wirings with a minute pitch increases by the fringe effect of the edges of the wirings. For example, even incase that hydrogen silsesquioxane (HSQ, hereinafter) or SiO₂ containing organic ingredient with a low specific dielectric constant is used, it becomes a cause of the signal delay.

### SUMMARY OF THE INVENTION

Accordingly, it is an object of the invention to provide a semiconductor device having a dual damascene structure and a method for fabricating the same in which a capacitance between wirings is reduced effectively and the wiring is formed so as not necessitate a silicon nitride layer.

According to the first feature of the invention, a semiconductor device comprises:

the first wiring provided for a Si substrate,

the second wiring formed on a higher layer than the Si substrate,

a via plug communicating with the higher layer and the Si substrate,

a damascene for accommodating the second wiring,

a via hole for accommodating the via plug,

the first insulating layer surrounding the via hole, and

the second and third insulating layers surrounding the damascene jointly, the third insulating layer being situated on the second insulating layer,

wherein etch rates of the first and second insulating layers change in different modes depending on a ratio of a flow rate of the first reactive gas to that of the second reactive gas.

In the semiconductor device according to claim 1, since the etch rates of the first and second insulating layers change in different modes depending on the ratio of the flow rate of the first reactive gas to that of the second reactive gas, the first insulating layer can be prevented from being etched in case that the damascene is formed by etching. Accordingly, since there is no necessity for forming a stopper layer formed of silicon nitride, such as SiN or SiON, directly under the wiring layer formed on the higher layer than the Si substrate, a wiring capacitance between wirings can be reduced.

In the semiconductor device according to claim 2, the first insulating layer is a SiO₂ layer, the second insulating layer is a HSQ layer, and the third insulating layer is a SiO₂ layer.

In the semiconductor device according to claim 3, the lower layer of the first insulating layer is a HSQ layer, the higher layer of the first insulating layer is a SiO₂ layer, the second insulating layer is a HSQ layer, and the third insulating layer is a SiO₂ layer.

Moreover, in the semiconductor device according to claim 4 or 5, the HSQ layer contains carbon.

In the semiconductor device according to claim 2, 3, 4 or 5, since the HSQ layer is etched on condition that the etch rate of the HSQ layer is higher than that of the SiO₂ layer, the dual damascene structure having an adequate configuration can be obtained.

Since there is no necessity for forming a stopper layer between the insulating layers, a capacitance between wirings can be reduced.

According to the second feature of the invention, a method for fabricating a semiconductor device comprises the steps of:

successively forming the first insulating layer, the second insulating layer and the third insulating layer on a Si substrate provided with a wiring,

patterning the first resist on the third insulating layer,

forming a via hole by etching the third, second and first insulating layers to a top surface of the Si substrate using the first resist as a mask,

removing the first resist,

patterning the second resist on the third insulating layer or both the third insulating layer and a bottom surface of the via hole,

forming a damascene by etching the third and second insulating layers to a top surface of the first insulating layer using the second resist as a mask,

removing the second resist,

depositing barrier metal on inner surfaces of the damascene and the via hole,

filling the damascene and the via hole with metal having a high electric conductivity on the barrier metal, and

polishing a surface of metal filling the damascene,

wherein etch rates of the first and second insulating layers change in different modes depending on the ratio of a flow rate of the first reactive gas to that of the second reactive gas.

In the invention according to claim 6, since there is no necessity for forming a stopper layer formed of silicon nitride, such as SiN or SiON, directly under the metallic wiring formed on a higher layer than the Si substrate, the semiconductor device in which a capacitance between wirings is reduced can be fabricated.

In a method for fabricating a semiconductor device according to claim 7, the first insulating layer is a SiO₂ layer, the second insulating layer is a HSQ layer, and the third insulating layer is a SiO₂ layer.

In a method for fabricating a semiconductor device according to claim 8, a lower layer of the first insulating layer is a HSQ layer, a higher layer of the first insulating layer is a SiO₂ layer, the second insulating layer is a HSQ layer, and the third insulating layer is a SiO₂ layer.

In a method for fabricating a semiconductor device according to claim 9 or 10, the HSQ layer contains carbon.

In methods for fabricating a semiconductor device according to claim 6, 7, 8, 9 or 10, since the HSQ layer is etched on condition that the etch rate of the HSQ layer is higher than that of the SiO₂ layer, the semiconductor device having a dual damascene structure with an adequate configuration can be fabricated.

Moreover, since there is no necessity for forming a stopper layer between the insulating layers, the semiconductor device in which a wiring capacitance between wirings are reduced can be fabricated.

In a method for fabricating a semiconductor device according to claim 11, the ratio of the flow rate of fluorocarbon to that of oxygen is about 1.5 in the step of forming the via hole, and less than about 1.5 in the step of forming the damascene.

In the method for fabricating a semiconductor device according to claim 11, since the HSQ layer is etched on condition that the etch rate of the HSQ layer is higher than that of the SiO₂ layer, the semiconductor device having the dual damascene structure with an adequate configuration can be fabricated.

Moreover, since there is no necessity for forming a stopper layer between the insulating layers, the semiconductor device in which a wiring capacitance between wirings is reduced can be fabricated.

When the etching process in the step of forming the via hole is performed on condition that the ratio of the flow rate of fluorocarbon to that of oxygen is about 1.5, the etch rate of the SiO₂ layer and that of the HSQ layer are nearly the same. On the other hand, in case that the etching process in the step of forming the via hole is performed on condition that the ratio of the flow rate of fluorocarbon to that of oxygen deviates from about 1.5, the HSQ layer is apt or hard to be etched as compared with SiO₂ layer.

When the etching process in the step of forming the damascene is performed on condition that the ratio of the flow rate of flurocarbon to that of oxygen is less than about 1.5, the HSQ layer is apt to be etched as compared with the SiO₂ layer. Accordingly, it becomes possible to etch the HSQ layer only in condition that the SiO₂ layer is hardly etched. On the other hand, if the ratio of the flow rate of fluorocarbon to that of oxygen is more than 1.5 in the etching process in the step of forming the damascene, the etch rate of the HSQ layer is reduced. Accordingly, the etch rate of the HSQ layer approaches that of the SiO₂ layer. As a result, it becomes difficult to etch the HSQ layer only, and there is a possibility that the SiO₂ layer may be etched also.

### BRIEF DESCRIPTION OF THE DRAWINGS

The invention will be explained in more detail in conjunction with appended drawings, wherein:

FIGS. 1A to 1D show the steps of a method for fabricating a conventional semiconductor device,

FIG. 2 shows a fringe effect of wirings with a minute pitch of a conventional semiconductor device,

FIGS. 3A to 3E show the steps of a method for fabricating a semiconductor device according to a preferred embodiment of the invention,

FIG. 4 shows relations between the etch rates of a HSQ layer and a SiO₂ layer and the ratio of the flow rate of C₄F₈ to that of O₂, and

FIG. 5 show another preferred embodiment of the invention in which a structure of insulating layers is changed.

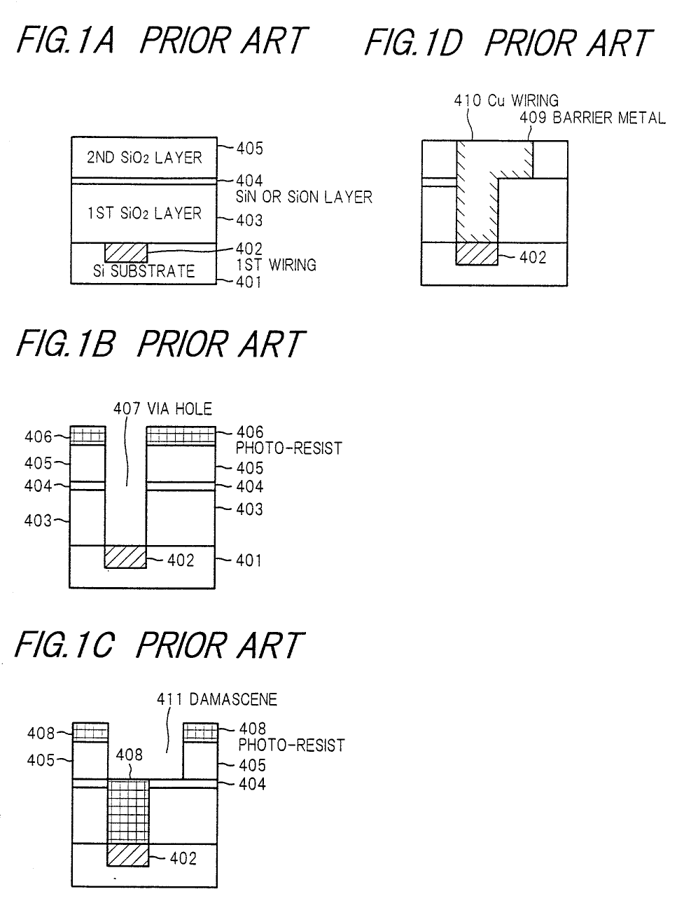

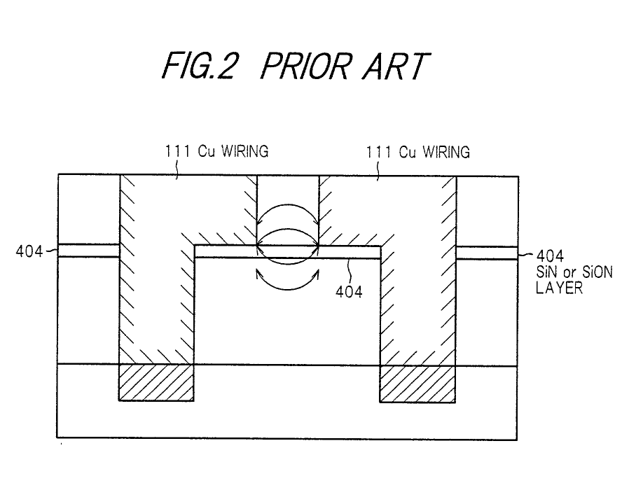

### DESCRIPTION OF THE PREFERRED EMBODIMENTS

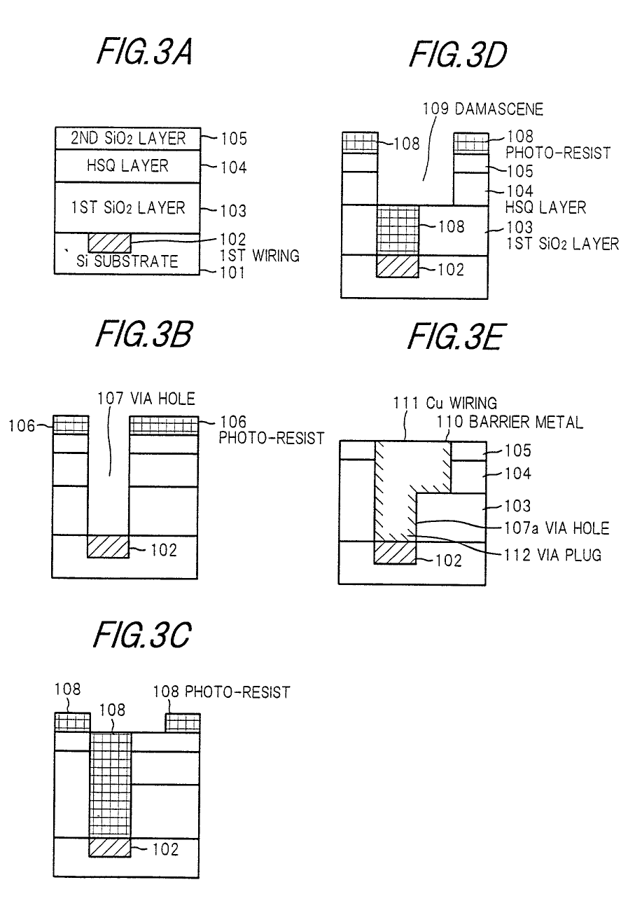

Preferred embodiments of the invention will be explained referring to FIGS. 3A to 3E, FIG. 4 and FIG. 5. FIGS. 3A to 3E shows the steps of a fabrication process of a semiconductor device according to a preferred embodiment of the invention. FIG. 3E shows a cross-sectional view of a completed semiconductor device according to a preferred embodiment of the invention.

A structure of the semiconductor device according to the invention is similar to that of the conventional semiconductor device except that the SiN or SiON layer and the SiO₂ layer formed thereon in the conventional semiconductor device are respectively replaced with a HSQ layer and a SiO₂ layer formed on the HSQ layer in the preferred embodiment of the invention.

That is to say, the semiconductor device according to the referred embodiment of the invention is composed of a Si substrate 101 provided with the first wiring 102, the first SiO₂ layer 103 formed on the Si substrate 101, a HSQ layer 104 formed on the first SiO₂ layer 103, the second SiO₂ layer 105 formed on the HSQ layer 104, barrier metal 110 deposited on inner surfaces of a damascene 109 and a via hole 107, and a Cu wiring 111 filling the damascene 109 and a via plug filling the via hole 107. In general, a size and a depth of the via hole 107 formed in the first SiO₂ layer 103 are different from those of the damascene 109 formed in the second SiO₂ layer 105 and the HSQ layer 104.

In the semiconductor device according to the preferred embodiment of the invention, a lower portion of the via hole 107 is filled with the via plug 112, which communicates with a higher layer on which the Cu wiring 111 (the second metallic wiring is situated and the Si substrate 101. The damascene 109 surrounded by the second SiO₂ layer 105 and the HSQ layer 104 accommodates a Cu wiring 111 (the second metallic wiring ). As shown in FIG. 3E, when the damascene 109 is formed, a higher portion of the via hole 107 is included in the damascene 109, and a lower portion of the same is filled with Cu (the via plug 112 ). Thereafter, the lower portion of the via hole 107 surrounded by the first SiO₂ layer 103 will be denoted by 107a after the damascene 109 is formed. Since an etch rate of the first SiO₂ layer 103 is different from that of the HSQ layer 104, it becomes possible to form the dual damascene structure in which the damascene 109 and the via hole 107 are formed in a lump.

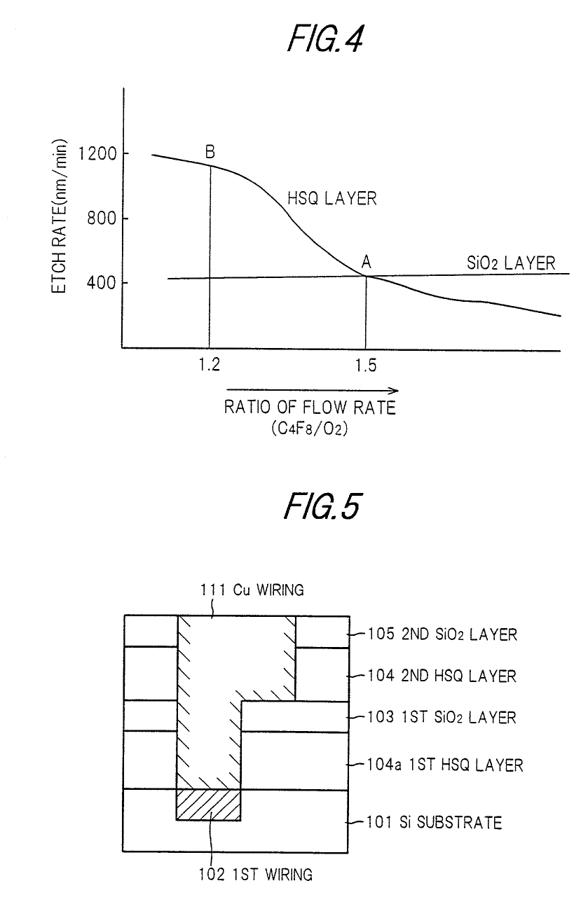

Next, the method for fabricating the semiconductor device according to the preferred embodiment of the invention will be explained referring to FIGS. 3A to 3E and FIG. 4. FIG. 4 shows a relation between the ratio of the flow rate of C₄F₈ to that of O₂ and the etch rate (nm/min) in case that the HSQ layer and the SiO₂ layer are respectively etched.

In the method for fabricating the semiconductor device according to the preferred embodiment of the invention, the first SiO₂ layer 103, the HSQ layer 104 and the second SiO₂ layer 105 are successively formed on the Si substrate 101 (FIG. 3A). Circuit elements, such as transistors etc., and the first wiring 102 are provided for the Si substrate 101. The via hole 107 is formed in the first SiO₂ layer 103, which is 300 to 1000 nm thick. The HSQ layer 104 is an insulating layer with a low dielectric constant, and the thickness thereof is 100 to 500 nm. Moreover, the second SiO₂ layer 105 is 30 to 200 nm thick.

Subsequently, a via hole 107 is formed by etching the second SiO₂ layer 105, the HSQ layer 104 and the first SiO₂ layer 103 to a top surface of the Si substrate 101 using a patterned photo-resist 106 as a mask (FIG. 3B).

The aforementioned etching process is performed by using mixed gas containing C₄F₈, O₂, CO and Ar. Since there is a relation shown in FIG. 4 between the ratio of the flow rate of C₄F₈ to that of O₂ and the etch rate, etching is performed in a condition corresponding to A in FIG. 4 in case that the via hole 107 is etched, where the etch rate of both the HSQ and SiO₂ layers is small (about 400 nm/min). In the condition corresponding to A in FIG. 4, the ratio of the flow rate of C₄F₈ to that of O₂ is about 1.5, power is about 2000 W, the flow rate of CO is 30 to 100 SCCM (standard cubic cm/minute), and that of Ar is 500 to 600 SCCM.

After the photo-resist 106 is removed, a new photo-resist 108 is again patterned (FIG. 3C). In this case, an anti-reflective coating (ARC) may be applied to the second SiO₂ layer 105 before the photo-resist 108 is applied thereto.

Next, the damascene 109 is etched in the condition corresponding to B in FIG. 4. That is to say, the etch rate of the HSQ layer (about 1100 nm/min) is higher than that of the SiO₂ layer. In the condition corresponding to B in FIG. 4, the ratio of the flow rate of C₄F₈ to that of O₂ is less than about 1.5. In the aforementioned condition, etch of the HSQ layer 104 is surely stopped at the first SiO₂ layer 103 without using a stopping layer formed of silicon nitride, such as SiN etc. The damascene 109 can be formed by the aforementioned process.

Then, after the photo-resist 108 is removed, barrier metal 110 formed of TaN etc. is deposited on the inner surfaces of the damascene 109 and the via hole 107a. Next, the damascene 109 and the via hole 107a are filled with Cu by electroplating. Thereafter, Cu is polished by CMP to form the Cu wiring 111, and a Cu dual damascene structure is completed (FIG. 3E) In this case, the via hole 107a is formed in the first SiO₂ layer 103. Moreover, the HSQ layer 104 may contain carbon of less than 15 weight percent.

In the dual damascene structure fabricated by a method for fabricating a semiconductor device according to the preferred embodiment of the invention, the HSQ layer 104 and the second SiO₂ layer 105 surround the damascene 109. In the multi-layered insulating layers shown in FIGS. 3A to 3E, the via hole 107 is etched in the first place, and the damascene 109 is etched subsequently.

When the damascene 109 is formed by etching the HSQ layer 104, the first SiO₂ layer 103 is prevented from being over-etched by performing the etching process on condition that the etch rate of the SiO₂ layer is lower than that of the HSQ layer.

In the method for fabricating the semiconductor device according to the preferred embodiment of the invention, since there is no necessity forming a stopper layer formed of silicon nitride, such as SiN or SiON, directly under the wiring, a wiring capacitance between wirings can be reduced. Moreover, the HSQ layer is inserted between the adjacent wirings, the capacitance between the wirings can be reduced. Since the wiring capacitance can be reduced by performing the etching process of the HSQ layer on condition that the etch rate of the SiO₂ layer is lower than that of the HSQ layer, it becomes possible to obtain the dual damascene structure having an adequate configuration.

In the semiconductor device according to the other preferred embodiment, a HSQ layer is formed at a position corresponding to a lower portion of the first SiO₂ layer 103, and a SiO₂ layer is formed at a position corresponding to a higher portion of the first SiO₂ layer 103 is formed as shown in FIG. 5. The structure of the semiconductor device shown in FIG. 5 is the same as that shown in FIG. 3E except a part corresponding to the first SiO₂ layer 103 shown in FIG. 3E.

The semiconductor device according to the preferred embodiment of the invention is composed of: the first wiring 102 provided for a Si substrate 101, the second wiring 111 formed on a higher layer than the Si substrate 101, a via plug 112 communicating with the higher layer and the Si substrate 101, a damascene 109 for accommodating the second wiring 111, a via hole 107a which accommodates the via plug 112 and communicates with the damascene 109 and the Si substrate 101, an insulating layer surrounding the damascene 109, which is composed of a HSQ layer 104 and the second insulating layer 105, the first SiO₂ layer 103 surrounding the via hole 107a, and barrier metal 110 deposited on inner surfaces of the damascene 109 and the via hole 107a, wherein the etch rates of the HSQ layer 104 and the first SiO₂ layer 103 change in different modes depending on the ratio of the flow rate of the first reactive gas to that of the second reactive gas. Accordingly, since there is no necessity for forming a stopper layer formed of silicon nitride, such as SiN or SiON, directly under the Cu wiring 111, the wiring capacitance between the wirings can be reduced.

The method for fabricating a semiconductor device according to a preferred embodiment of the invention comprises the steps of: successively forming the first SiO₂ layer 103, a HSQ layer 104 and the second SiO₂ layer 105 on a Si substrate 101 provided with the first wiring 102, patterning the first resist 106 on the second SiO₂ layer 105, forming a via hole 107 by etching the second SiO₂ layer 105, the HSQ layer 104 and the first SiO₂ layer 103 to a top surface of the Si substrate 101 using the first resist 106 as a mask, removing the first resist 106, patterning the second resist 108 on the second SiO₂ layer 105 or both the second SiO₂ layer 105 and a bottom surface of the via hole 107, forming a damascene 109 by etching the second SiO₂ layer 105 and the HSQ layer 104 to a top surface of the first SiO₂ layer 103 using the second resist 108 as a mask, removing the second resist 108, depositing barrier metal 110 on inner surfaces of the damascene 109 and the via hole 107a, filling the damascene 109 and the via hole 107a with Cu having a high electric conductivity on barrier metal 110, and polishing surfaces of a Cu wiring 111 and the second SiO₂ layer 105, wherein the etch rates of the HSQ layer 104 and the first SiO₂ layer 103 change in different modes depending on the flow rate of the first reactive gas to that of the second reactive gas. Accordingly, since there is no necessity for forming a stopper layer formed of silicon nitride; such as SiN or SiON, directly under the wiring 111 formed on a higher layer than the Si substrate 101, the semiconductor device in which a wiring capacitance between wirings are reduced can be fabricated.

In the semiconductor device according to the invention, since there is no necessity for forming a stopper layer formed of silicon nitride, such as SiN or SiON, directly under a wiring formed on a higher layer than the Si substrate, a wiring capacitance between wirings can be reduced. Moreover, since the HSQ layer is etched on condition that the etch rate of the HSQ layer is higher than that of the SiO₂ layer, the dual damascene structure having an adequate configuration can be obtained.

Although the invention has been described with respect to specific embodiment for complete and clear disclosure, the appended claims are not to be thus limited but are to be construed as embodying all modification and alternative constructions that may be occurred to one skilled in the art which fairly fall within the basic teaching here is set forth.

What is claimed is:

1. A semiconductor device comprising:
a first wiring provided for a Si substrate,
a second wiring formed on a higher layer than said Si substrate,
a via plug communicating with said higher layer and said Si substrate,
a damascene for accommodating said second wiring,
a via hole for accommodating said via plug,
a first insulating layer surrounding said via hole, and
second and third insulating layers surrounding said damascene jointly, said third insulating layer being situated on said second insulating layer,
wherein etch rates of said first and second insulating layers change in different modes depending on a ratio of a flow rate of first reactive gas to that of second reactive gas.

2. A semiconductor device according to claim 1, wherein:
said first insulating layer is a SiO₂ layer,
said second insulating layer is a hydrogen silsesquioxane (HSQ, hereinafter) layer, and
said third insulating layer is a SiO₂ layer.

3. A semiconductor device according to claim 1, wherein:
a lower layer of said first insulating layer is a HSQ layer,
a higher layer of said first insulating layer is a SiO₂ layer,
said second insulating layer is a HSQ layer, and
third insulating layer is a SiO₂ layer.

4. A semiconductor device according to claim 2, whrerein:
said HSQ layer contains carbon.

5. A semiconductor device according to claim 3, wherein:
said HSQ layer contains carbon.

6. A method for fabricating a semiconductor device comprising the steps of:
successively forming a first insulating layer, a second insulating layer and a third insulating layer on a Si substrate provided with a wiring,
patterning a first resist on said third insulating layer,
forming a via hole by etching said third, second and first insulating layers to a top surface of said Si substrate using said first resist as a mask,
removing said first resist,
patterning a second resist on said third insulating layer or both said third insulating layer and a bottom surface of said via hole,
forming a damascene by etching said third and second insulating layers to a top surface of said first insulating layer using said second resist as a mask,
removing said second resist,
depositing barrier metal on inner surfaces of said damascene and said via hole,
filling said damascene and said via hole with metal having a high electric conductivity on said barrier metal, and
polishing a surface of said metal filling said damascene,
wherein etch rates of said first and second insulating layers change in different modes depending on a ratio of a flow rate of first reactive gas to that of second reactive gas.

7. A method for fabricating a semiconductor device according to claim 6, wherein:
said first insulating layer is a SiO₂ layer,
said second insulating layer is a HSQ layer, and
said third insulating layer is a SiO₂ layer.

8. A method for fabricating a semiconductor device according to claim 6, wherein:
a lower layer of said first insulating layer is a HSQ layer,
a higher layer of said first insulating layer is a SiO₂ layer,
said second insulating layer is a HSQ layer, and
said third insulating layer is a SiO₂ layer.

9. A method for fabricating a semiconductor device according to claim 7, wherein:
said HSQ layer contains carbon.

10. A method for fabricating a semiconductor device according to claim 8, wherein:
said HSQ layer contains carbon.

11. A method for fabricating a semiconductor device according to claim 6, wherein:
said first reactive gas is fluorocarbon,
said second reactive gas is oxygen,
said ratio of said flow rate of fluorocarbon to that of oxygen is about 1.5 in said step of forming said via hole, and
said ratio of said flow rate of fluorocarbon to that of oxygen is less than about 1.5 in said step of forming said damascene.
